(19) United States
(12) Patent Application Publication
(10) Pub. No.: US 2026/0324222 A1
(43) Pub. Date: Oct. 15, 2026

(54) DISPLAY DEVICE AND ELECTRONIC DEVICE COMPRISING THE SAME

(71) Applicant: Samsung Display Co., LTD., Yongin-si (KR)

(72) Inventors: HOYOUNG SIM, Yongin-si (KR); Hee Jun YANG, Yongin-si (KR)

(21) Appl. No.: 19/465,090

(22) Filed: Jan. 30, 2026

(30) Foreign Application Priority Data
Mar. 11, 2025 (KR) 10-2025-0031538

(51) Int. Cl. H10K 59/131

(52) U.S. Cl. CPC H10K 59/131

(57) ABSTRACT

A display device includes a substrate, a pixel circuit portion positioned on the substrate, an auxiliary wiring layer positioned on the pixel circuit portion, a first electrode positioned on the auxiliary wiring layer, a light emitting layer positioned on the first electrode, a second electrode positioned on the light emitting layer and electrically connected to the auxiliary wiring layer. The auxiliary wiring layer includes a first auxiliary wiring layer positioned on the pixel circuit portion, a second auxiliary wiring layer positioned on the first auxiliary wiring layer. A side surface of the third auxiliary wiring layer and an outer side surface of the light emitting layer are coplanar to form the same inclined surface with respect to a lower surface of the third auxiliary wiring layer.

This application claims priority to Korean Patent Application No. 10-2025-0031538, filed on Mar. 11, 2025, and all the benefits accruing therefrom under 35 U.S.C. §119, the content of which in its entirety is herein incorporated by reference.

### BACKGROUND

### 1. Field

This disclosure relates to a display device and an electronic device comprising the same.

### 2. Description of the Related Art

A display device is a device that displays images of image data. Recently, light emitting diode displays are being developed as self-emitting display devices.

Each pixel includes a plurality of transistors and a light emitting element. The plurality of transistors are connected to signal lines and can supply driving current to the light emitting element. The light emitting element includes an anode, a cathode, and a light emitting layer positioned between the anode and the cathode, and the anode can be connected to a transistor of the pixel to receive driving current. The light emitting element can be implemented as a light emitting diode, and the light emitting diode can emit light when holes from the anode and electrons from the cathode meet in the light emitting layer.

A sealing layer may be positioned on the upper part of the light emitting element to prevent defects caused by moisture permeation from the outside.

### SUMMARY

Embodiments provide a display device with improved reliability and an electronic device comprising the same.

A display device according to an embodiment includes a substrate, a pixel circuit portion positioned on the substrate, an auxiliary wiring layer positioned on the pixel circuit portion, a first electrode positioned on the auxiliary wiring layer, a light emitting layer positioned on the first electrode, and a second electrode positioned on the light emitting layer and electrically connected to the auxiliary wiring layer, where the auxiliary wiring layer includes a first auxiliary wiring layer positioned on the pixel circuit portion, a second auxiliary wiring layer positioned on the first auxiliary wiring layer, and a third auxiliary wiring layer positioned on the second auxiliary wiring layer. A side surface of the third auxiliary wiring layer and an outer side surface of the light emitting layer are coplanar to form a same inclined surface with respect to a lower surface of the third auxiliary wiring layer.

The display device may further include a first insulation layer positioned between the third auxiliary wiring layer and the first electrode, and an edge of the first insulation layer may overlap with an edge of the third auxiliary wiring layer.

The display device may further include a second insulation layer positioned on the first insulation layer and the first electrode, and another edge of the first insulation layer and an edge of the second insulation layer may overlap with each other.

The light emitting layer may cover an upper surface of the second insulation layer and an upper surface of the first electrode.

The light emitting layer may be spaced apart from a side surface of the first insulation layer and a side surface of the second insulation layer.

The second electrode may contact the side surface of the third auxiliary wiring layer.

The third auxiliary wiring layer and the second auxiliary wiring layer may form an undercut structure between the third auxiliary wiring layer and the second auxiliary wiring layer.

The second auxiliary wiring layer and the third auxiliary wiring layer may have an island shape.

A width of the third auxiliary wiring layer may be greater than a width of the second auxiliary wiring layer.

The second electrode may surround the light emitting layer and the first electrode.

The display device may further include an auxiliary electrode positioned on the first auxiliary wiring layer.

The auxiliary electrode may include the same material as the second electrode.

The display device may further include a first inorganic layer positioned on the second electrode and the auxiliary electrode.

The substrate may include a first color emission area, a second color emission area, and a third color emission area, the second electrode may be provided in plurality, the second electrodes may be provided in the first color emission area, the second color emission area, and the third color emission area, respectively, and the second electrodes may be spaced apart from each other.

The first auxiliary wiring layer may be monolithically arranged across the first color emission area, the second color emission area, and the third color emission area.

The first inorganic layer may be provided in plurality, the first inorganic layers may be provided in the first color emission area, the second color emission area, and the third color emission area, respectively, and the first inorganic layers may be spaced apart from each other.

In an electronic device including a display device according to an embodiment, the display device includes a substrate, a pixel circuit portion positioned on the substrate, an auxiliary wiring layer positioned on the pixel circuit portion, a first electrode positioned on the auxiliary wiring layer, a light emitting layer positioned on the first electrode, and a second electrode positioned on the light emitting layer and electrically connected to the auxiliary wiring layer, where the auxiliary wiring layer includes a first auxiliary wiring layer positioned on the pixel circuit portion, a second auxiliary wiring layer positioned on the first auxiliary wiring layer, and a third auxiliary wiring layer positioned on the second auxiliary wiring layer, and a side surface of the third auxiliary wiring layer and an outer side surface of the light emitting layer are coplanar to form the same inclined surface with respect to a lower surface of the third auxiliary wiring layer.

The electronic device may be at least one of a smartphone, a tablet PC, a laptop, a TV, a desktop monitor, a wearable electronic device, and a vehicle electronic device.

The light emitting layer may be spaced apart from a side surface of the first insulation layer and a side surface of the second insulation layer.

The second electrode may contact the side surface of the third auxiliary wiring layer.

In an electronic device including a display device, the display device includes a substrate, a pixel circuit portion positioned on the substrate, an auxiliary wiring layer positioned on the pixel circuit portion, a first electrode positioned on the auxiliary wiring layer, a light emitting layer positioned on the first electrode, and a second electrode positioned on the light emitting layer and connected to the auxiliary wiring layer, where the auxiliary wiring layer includes a first auxiliary wiring layer positioned on the pixel circuit portion, a second auxiliary wiring layer positioned on the first auxiliary wiring layer, and a third auxiliary wiring layer positioned on the second auxiliary wiring layer, and a width of the third auxiliary wiring layer is greater than a width of the second auxiliary wiring layer, and the light emitting layer is spaced apart from the auxiliary wiring layer.

The light emitting layer may be spaced apart from a side surface of the auxiliary wiring layer.

The second electrode may contact at least a portion of a side surface of the auxiliary wiring layer.

The display device may further include a first inorganic layer positioned on the second electrode, and the first inorganic layer may encapsulate the second electrode.

According to embodiments, the reliability of the display device and the electronic device comprising the same can be effectively improved.

### BRIEF DESCRIPTION OF THE DRAWINGS

FIG. 1 is a block diagram of an electronic device according to an embodiment.

FIG. 2 is a schematic diagram of electronic devices according to various embodiments.

FIG. 3 is a perspective view of an electronic device according to an embodiment.

FIG. 4 is an exploded perspective view of an electronic device according to an embodiment.

FIG. 5 is a plan view of some pixels in a display device according to an embodiment.

FIG. 6 is a cross-sectional view taken along lines A-A', A’-A'', and A’’-A''' of FIG. 5.

FIG. 7 is a cross-sectional view of the A-A' region of FIG. 6.

FIG. 8 is an enlarged view of the AA region of FIG. 7.

FIG. 9 is a cross-sectional view of the display device along B-B' of FIG. 5.

FIG. 10 is a cross-sectional view of the display device along C-C' of FIG. 5.

FIG. 11 is a flowchart of a manufacturing process of a display device according to an embodiment.

FIGS. 12, 13, and 14 are cross-sectional views of a manufacturing process of a display device according to an embodiment.

### DETAILED DESCRIPTION

Hereinafter, various embodiments of the present disclosure will be described in detail with reference to the accompanying drawings so that those skilled in the art to which the present disclosure pertains can easily practice the disclosure. The present disclosure can be implemented in various different forms and is not limited to the embodiments described herein.

To clearly explain the present disclosure, parts not related to the description have been omitted, and the same or similar components are designated by the same reference numerals throughout the specification.

Also, the size and thickness of each component shown in the drawings are arbitrarily shown for the convenience of description, so the present disclosure is not necessarily limited to what is shown. The thickness is enlarged to clearly express various layers and regions in the drawings. In the drawings, for the convenience of explanation, the thickness of some layers and regions is exaggerated.

Also, when a part such as a layer, film, region, or plate is described as being "on" or "above" another part, it includes not only the case where it is "directly on" the other part, but also the case where another part is present in between. Conversely, when a part is described as being "directly on" another part, it means that there is no other part in between. Also, being "on" or "above" a reference part means being located above or below the reference part, and does not necessarily mean being located in the direction opposite to gravity.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, "a", "an," "the," and “at least one” do not denote a limitation of quantity, and are intended to include both the singular and plural, unless the context clearly indicates otherwise. For example, "an element" has the same meaning as “at least one element," unless the context clearly indicates otherwise. “At least one” is not to be construed as limiting “a” or “an.” “Or” means “and/or.” As used herein, the term “and/or” includes any and all combinations of one or more of the associated listed items.

Also, throughout the specification, when a part "includes" a component, it means that, unless there is a particular description to the contrary, it may further include other components rather than excluding other components.

Also, throughout the specification, "in a plan view" means viewing the target part from above (i.e., view in a thickness direction (i.e., third direction DR3) of a substrate SUB), and "in a cross-sectional view" means viewing a cross-section of the target part cut vertically from the side.

A display device according to an embodiment can be applied to various electronic devices. An electronic device according to an embodiment includes the display device described below, and may further include modules or devices having additional functions other than the display device.

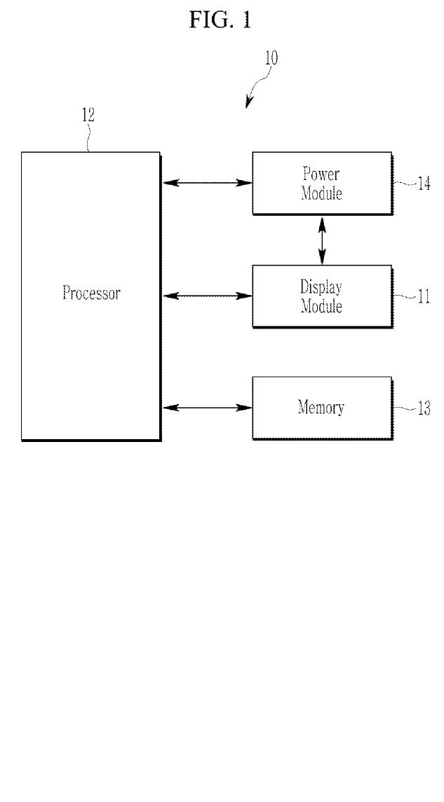

FIG. 1 is a block diagram of an electronic device according to an embodiment. Referring to FIG. 1, an electronic device 10 according to an embodiment may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller.

The memory 13 may store data needed for the operation of the processor 12 or the display module 11. When the processor 12 executes an application stored in the memory 13, image data signals and/or input control signals are transmitted to the display module 11, and the display module 11 processes the provided signals to output image information through the display screen.

The power module 14 may include a power supply module such as a power adapter or a battery device, and a power conversion module that converts power supplied by the power supply module to generate power for the operation of the electronic device 10.

At least one of the components of the electronic device 10 described above may be included in the display device according to embodiments. Also, some of the individual modules included in one module functionally may be included in the display device, and the other parts may be provided separately from the display device. For example, the display device may include the display module 11, and the processor 12, the memory 13, and the power module 14 may be provided in the form of other devices in the electronic device 10 other than the display device.

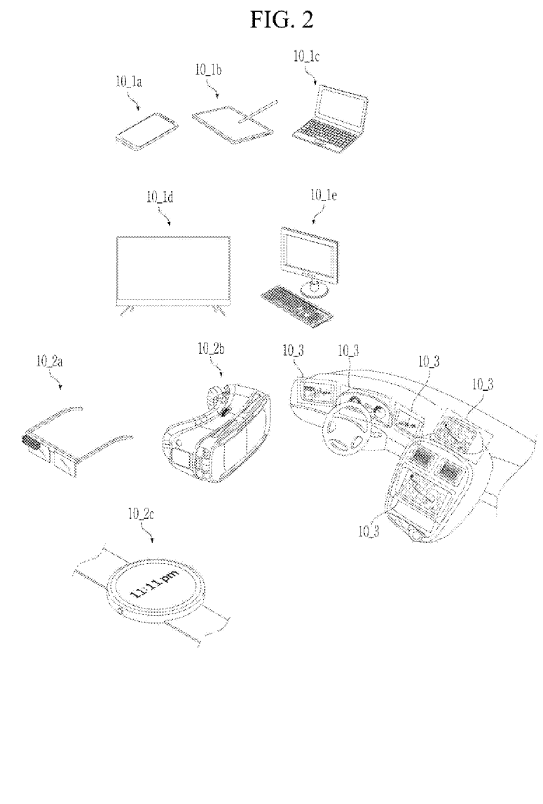

Hereinafter, various embodiments of electronic devices will be examined with reference to FIG. 2. FIG. 2 is a schematic diagram of electronic devices according to various embodiments.

Referring to FIG. 2, various electronic devices to which the display device according to embodiments is applied may include not only image display electronic devices such as a smartphone 10_1a, a tablet PC 10_1b, a laptop 10_1c, a TV 10_1d, a desktop monitor 10_1e, but also wearable electronic devices including a display module such as smart glasses 10_2a, a head mounted display 10_2b, a smart watch 10_2c, and vehicle electronic devices including a display module such as an instrument panel, a center fascia, a Center Information Display (CID) arranged on a dashboard, a room mirror display, and the like.

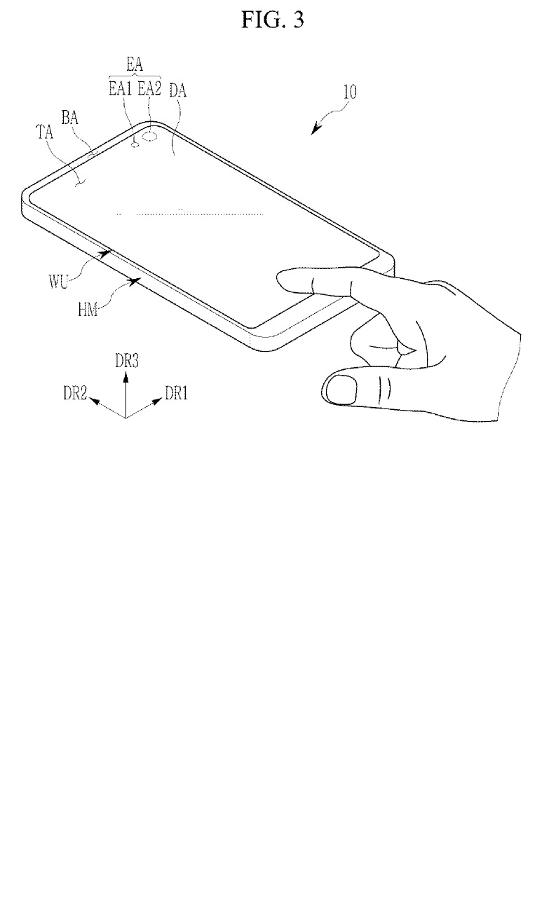

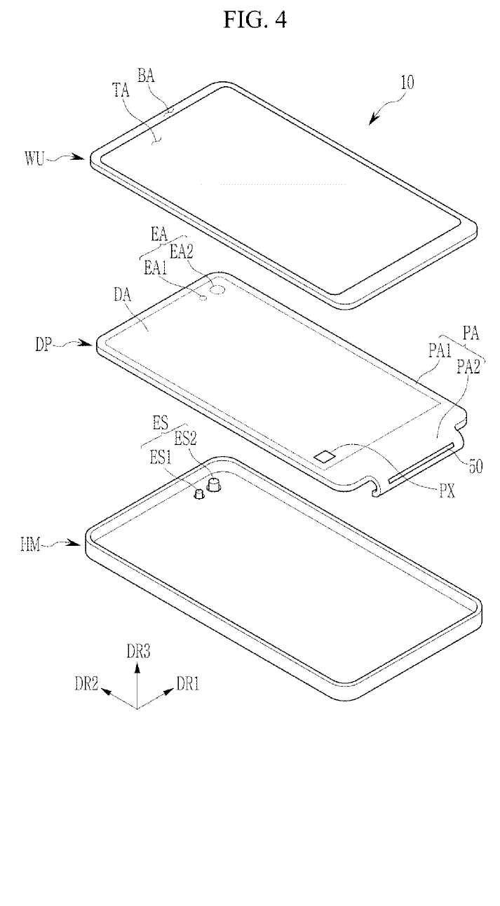

Hereinafter, an example of the electronic devices described above will be examined with reference to FIGS. 3 and 4. FIG. 3 is a schematic perspective view showing the usage state of an electronic device according to an embodiment, and FIG. 4 is an exploded perspective view of an electronic device according to an embodiment.

Referring to FIGS. 3 and 4, an electronic device 10 according to an embodiment is shown as being used as a smartphone for convenience of explanation, but any electronic device in FIG. 2 can be applied.

The electronic device 10 can display images toward a third direction DR3 on a display surface parallel to each of a first direction DR1 and a second direction DR2. The display surface on which the image is displayed may correspond to the front surface of the display device included in the electronic device 10, and may correspond to the front surface of the cover window WU. The image may include not only dynamic images but also still images.

In this embodiment, the front surface (or upper surface) and the back surface (or lower surface) of each member are defined based on the direction in which the image is displayed. The front surface and the back surface are opposing each other in the third direction DR3, and the normal direction of each of the front surface and the back surface may be parallel to the third direction DR3. The separation distance between the front surface and the back surface in the third direction DR3 may correspond to the thickness of the display device in the third direction DR3.

An electronic device 10 according to an embodiment can detect a user's input (see the hand in FIG. 3) applied from the outside. The user's input may include various forms of external inputs such as a part of the user's body, light, heat, or pressure. In one embodiment, the user's input is illustrated as the user's hand applied to the front surface. However, the present disclosure is not limited thereto. The user's input can be provided in various forms, and the electronic device 10 can also detect the user's input applied to the side or back of the electronic device 10 depending on the structure of the electronic device 10.

Referring to FIGS. 3 and 4, the electronic device 10 may include a cover window WU, a housing HM, a display device DP, and an optical element ES. In one embodiment, the cover window WU and the housing HM may be combined to form the exterior of the electronic device 10.

The cover window WU may include an insulating panel. For example, the cover window WU may be made of glass, plastic, or a combination thereof.

The front surface of the cover window WU may define the front surface of the electronic device 10. The transmission area TA may be an optically transparent area. For example, the transmission area TA may be an area with a visible light transmittance of about 90% or more.

The blocking area BA may define the shape of the transmission area TA. The blocking area BA is adjacent to the transmission area TA and may surround the transmission area TA. The blocking area BA may be an area with a relatively low light transmittance compared to the transmission area TA. The blocking area BA may include an opaque material that blocks light. The blocking area BA may have a predetermined color.

The display device DP may include display pixels PX that display images and a driving unit 50. The display pixels PX are located within the display area DA and the component area EA. The display device DP may include a front surface including a display area DA and a non-display area PA. In one embodiment, the display area DA and the component area EA are areas where images are displayed including pixels, and at the same time, they may be areas where external inputs are detected with a touch sensor located above the pixels in the third direction DR3.

The transmission area TA of the cover window WU may overlap at least partially with the display area DA and the component area EA of the display device DP. For example, the transmission area TA may overlap with the front surface of the display area DA and the component area EA, or may overlap with at least a portion of the display area DA and the component area EA. Accordingly, the user may view images through the transmission area TA or provide external input based on the images. However, the present disclosure is not limited thereto. For example, the area where the image is displayed and the area where the external input is detected may be separated from each other.

The non-display area PA of the display device DP may overlap at least partially with the blocking area BA of the cover window WU. The non-display area PA may be an area covered by the blocking area BA. The non-display area PA is adjacent to the display area DA and may surround the display area DA. The non-display area PA does not display images, and driving circuits or driving wiring for driving the display area DA may be arranged. The non-display area PA may include a first peripheral area PA1 where the display area DA is located on the outside, and a second peripheral area PA2 including a driving unit 50, connection wiring, and a bending area.

Also, the component area EA of the display device DP may include a first component area EA1 and a second component area EA2. The first component area EA1 and the second component area EA2 may be at least partially surrounded by the display area DA. The first component area EA1 and the second component area EA2 are shown to be spaced apart from each other, but are not limited thereto and may be at least partially connected. The first component area EA1 and the second component area EA2 may be areas where optical elements (refer to ES in FIG. 4; hereinafter also referred to as components) using infrared, visible light, or sound are arranged thereunder.

The display area DA (hereinafter also referred to as the main display area) and the component area EA are formed with a plurality of light emitting diodes, and a plurality of pixel circuit portions that generate and deliver emission current to each of the plurality of light emitting diodes. Here, one light emitting diode and one pixel circuit portion are called a pixel PX. In the display area DA and the component area EA, one pixel circuit portion and one light emitting diode may be formed in a one-to-one manner.

The first component area EA1 may include a transmission portion through which light and/or sound can pass and a display portion including a plurality of pixels. The transmission portion is positioned between adjacent pixels and consists of a layer through which light and/or sound can pass. The transmission portion may be positioned between adjacent pixels, and according to embodiments, a layer that does not transmit light, such as a light blocking member, may overlap with the first component area EA1. The number of pixels per unit area (hereinafter also referred to as resolution) of the pixels included in the display area DA (hereinafter also referred to as normal pixels) and the number of pixels per unit area of the pixels included in the first component area EA1 (hereinafter also referred to as first component pixels) may be the same.

The second component area EA2 includes an area composed of a transparent layer through which light can pass (hereinafter also referred to as a light transmission area), and the light transmission area has a structure that does not block light by having no conductive layer or semiconductor layer positioned therein, and by including an opening that overlaps with a position corresponding to the second component area EA2 in a layer containing a light blocking material, for example, a pixel defining layer and/or a light blocking member. The number of pixels per unit area of the pixels included in the second component area EA2 (hereinafter also referred to as second component pixels) may be smaller than the number of pixels per unit area of the normal pixels included in the display area DA. As a result, the resolution of the second component pixels may be lower than the resolution of normal pixels.

According to embodiments, a light blocking area can be formed by overlapping at least two-color filters instead of a light blocking member to block light of specific wavelengths (for example, visible light, or the like).

The driving unit 50 may be mounted on the second peripheral area PA2, and may be mounted on a bending part or located on at least one of the two sides of the bending part. The driving unit 50 may be provided in the form of a chip.

The driving unit 50 may be electrically connected to the display area DA and the component area EA to deliver electrical signals to the pixels of the display area DA and the component area EA. For example, the driving unit 50 may provide data signals to the pixels PX arranged in the display area DA. Alternatively, the driving unit 50 may include a touch driving circuit and may be electrically connected to touch sensors arranged in the display area DA and/or the component area EA. In addition, the driving unit 50 may include various circuits other than the above-described circuits or may be designed to provide various electrical signals to the display area DA.

A pad portion may be located at the end of the second peripheral area PA2, and may be electrically connected to a flexible printed circuit board (FPCB) including a driving chip through the pad portion. Here, the driving chip located on the flexible printed circuit board may include various driving circuits for driving the display device DP or connectors for power supply. According to embodiments, a rigid printed circuit board (PCB) may be used instead of a flexible printed circuit board.

The optical element ES may be arranged under the display device DP. The optical element ES may include a first optical element ES1 overlapping with the first component area EA1 and a second optical element ES2 overlapping with the second component area EA2. The first optical element ES1 may use infrared light, in which case the first component area EA1 may have a layer that does not transmit light, such as a light blocking member, overlapping with the first component area EA1.

The first optical element ES1 may be an electronic element that uses light or sound. For example, the first optical element ES1 may be a sensor that receives and uses light such as an infrared sensor, a sensor that outputs and detects light or sound to measure distance or recognize fingerprints, or the like, a small lamp that outputs light, or a speaker that outputs sound. In the case of electronic elements using light, it is of course possible to use light of various wavelength bands such as visible light, infrared light, ultraviolet light, or the like.

The second optical element ES2 may be at least one of a camera, an IR camera, a dot projector, an IR illuminator, and a Time-of-Flight (ToF) sensor.

The housing HM may be combined with the cover window WU. The cover window WU may be arranged on the front surface of the housing HM. The housing HM may be combined with the cover window WU to provide a predetermined accommodation space. The display device DP and the optical element ES may be accommodated in the predetermined accommodation space provided between the housing HM and the cover window WU.

The housing HM may include a material with relatively high rigidity. For example, the housing HM may include glass, plastic, or metal, or may include a plurality of frames and/or plates composed of a combination thereof. The housing HM can stably protect the components of the electronic device 10 accommodated in the internal space from external impacts.

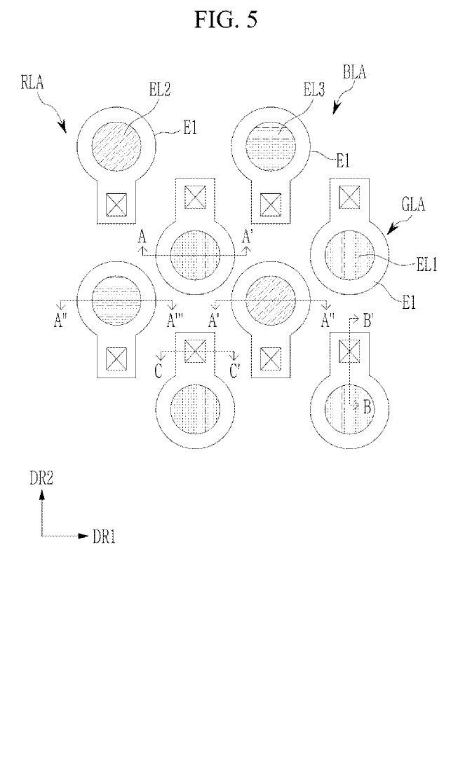

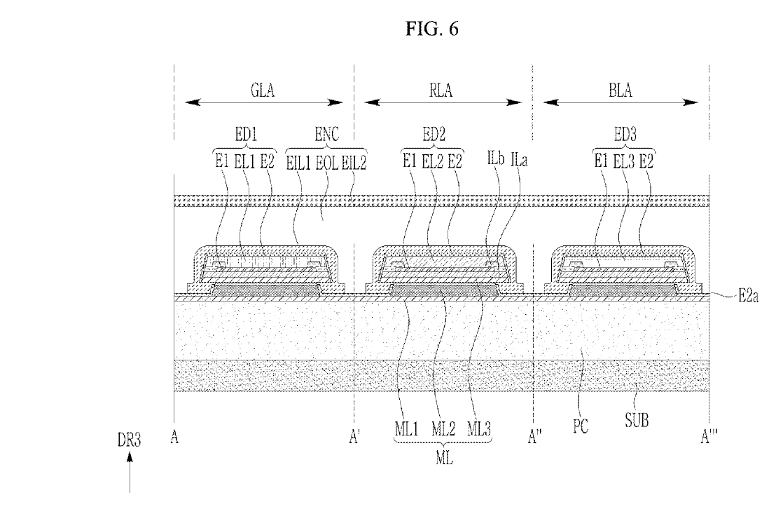

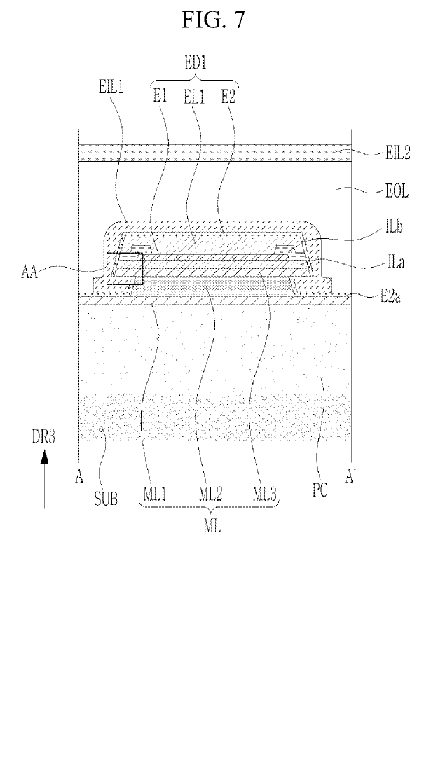

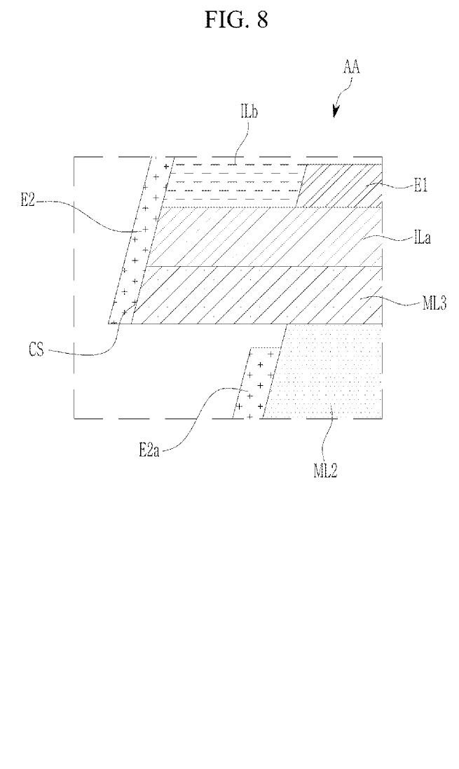

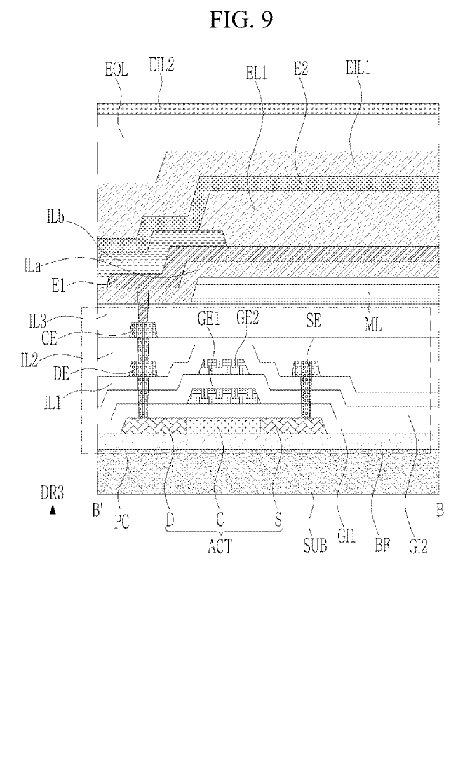

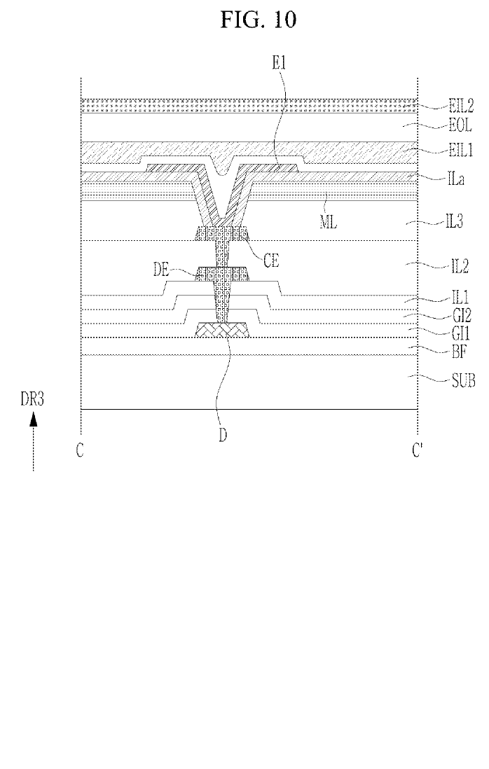

Hereinafter, some pixels in a display device according to an embodiment will be examined with reference to FIGS. 5-10. FIG. 5 is a plan view of some pixels of a display device applied to electronic devices, FIG. 6 is a cross-sectional view taken along lines A-A', A’-A'', and A’’-A''' of FIGS. 5, FIG. 7 is a cross-sectional view of A-A' of FIG. 5, FIG. 8 is an enlarged view of the AA region of FIG. 7, FIG. 9 is a cross-sectional view of B-B' of FIGS. 5, and FIG. 10 is a cross-sectional view of C-C' of FIG. 5.

A display device according to an embodiment includes a display area (DA in FIG. 4) where a plurality of pixels capable of displaying images are located. The display area may include a first color emission area GLA, a second color emission area RLA, and a third color emission area BLA as shown in FIG. 5.

The first color emission area GLA, the second color emission area RLA, and the third color emission area BLA may be repeatedly arranged along the first direction DR1 and the second direction DR2 in the display device DP in FIG. 4. For example, the second color emission area RLA, the first color emission area GLA, the third color emission area BLA, and the first color emission area GLA may be repeatedly arranged along the first direction DR1, but the order is not limited to this.

FIG. 5 shows three types of areas that can emit light of different colors, but is not limited thereto, and may include a plurality of emission areas that can emit light of four different colors. For example, the first color emission area GLA may emit green light, the second color emission area RLA may emit red light, and the third color emission area BLA may emit blue light, and according to embodiments, a fourth color emission area that can emit white light may be further included.

Referring next to FIG. 6, each of the first to third color emission areas GLA, RLA, and BLA may include a pixel circuit portion PC including at least one transistor and a light emitting element ED1, ED2, and ED3 that is electrically connected to the pixel circuit portion PC and can emit light.

The first color emission area GLA may include a first light emitting element ED1 electrically connected to the pixel circuit portion PC. The second color emission area RLA may include a second light emitting element ED2 electrically connected to the pixel circuit portion PC. The third color emission area BLA may include a third light emitting element ED3 electrically connected to the pixel circuit portion PC. The first light emitting element ED1 may emit green light, the second light emitting element ED2 may emit red light, and the third light emitting element ED3 may emit blue light, but is not limited thereto.

A display device according to an embodiment includes a substrate SUB. The substrate SUB may include a flexible material such as plastic that can be easily bent, folded, or rolled. According to embodiments, the substrate SUB may include a first color emission area GLA, a second color emission area RLA, and a third color emission area BLA.

On the substrate SUB is positioned a pixel circuit portion PC including at least one transistor. The detailed structure of the pixel circuit portion will be described later with reference to FIG. 9.

An auxiliary wiring layer ML may be positioned on the pixel circuit portion PC. The auxiliary wiring layer ML may extend to the peripheral area surrounding the display area to receive a common voltage.

The auxiliary wiring layer ML may consist of a triple layer. The auxiliary wiring layer ML may include a first auxiliary wiring layer ML1, a second auxiliary wiring layer ML2, and a third auxiliary wiring layer ML3.

The first auxiliary wiring layer ML1, the second auxiliary wiring layer ML2, and the third auxiliary wiring layer ML3 may include conductive materials such as metals like copper (Cu), molybdenum (Mo), titanium (Ti), aluminum (Al), and transparent conductive oxides. According to one embodiment, the first auxiliary wiring layer ML1 and the third auxiliary wiring layer ML3 may include the same material, and the second auxiliary wiring layer ML2 may include a different material from the first auxiliary wiring layer ML1 and the third auxiliary wiring layer ML3. For example, the first auxiliary wiring layer ML1 and the third auxiliary wiring layer ML3 may include titanium, and the second auxiliary wiring layer ML2 may include aluminum.

The first auxiliary wiring layer ML1 may be arranged on the pixel circuit portion PC. The first auxiliary wiring layer ML1 may be arranged across the entire surface of the substrate SUB. Being arranged across the entire surface of the substrate SUB may mean that it is located on most of the surface of the substrate SUB, except for being removed in some areas for the anode (the first electrode to be described later) to contact the transistor. Alternatively, according to embodiments, the first auxiliary wiring layer ML1 may be provided in a planar mesh form across the entire surface of the substrate SUB. The first auxiliary wiring layer ML1 may extend to the non-display area and be electrically connected to a wiring that applies a common voltage.

The first auxiliary wiring layer ML1 may be located in the first color emission area GLA, the second color emission area RLA, and the third color emission area BLA. The first auxiliary wiring layer ML1 overlapping with the first color emission area GLA, the first auxiliary wiring layer ML1 overlapping with the second color emission area RLA, and the first auxiliary wiring layer ML1 overlapping with the third color emission area BLA may be continuously connected.

The second auxiliary wiring layer ML2 may be positioned on the first auxiliary wiring layer ML1. The second auxiliary wiring layer ML2 may be spaced apart for each pixel. The second auxiliary wiring layer ML2 may be provided in an island shape. The second auxiliary wiring layer ML2 located in the first color emission area GLA, the second auxiliary wiring layer ML2 located in the second color emission area RLA, and the second auxiliary wiring layer ML2 located in the third color emission area BLA may be spaced apart from each other. The second auxiliary wiring layer ML2 located in the first color emission area GLA, the second auxiliary wiring layer ML2 located in the second color emission area RLA, and the second auxiliary wiring layer ML2 located in the third color emission area BLA may be arranged independently of each other. The second auxiliary wiring layer ML2 located in the first color emission area GLA, the second auxiliary wiring layer ML2 located in the second color emission area RLA, and the second auxiliary wiring layer ML2 located in the third color emission area BLA may be separated from each other.

The third auxiliary wiring layer ML3 may be positioned on the second auxiliary wiring layer ML2. The third auxiliary wiring layer ML3 may be spaced apart for each pixel. The third auxiliary wiring layer ML3 may be provided in an island shape. The third auxiliary wiring layer ML3 located in the first color emission area GLA, the third auxiliary wiring layer ML3 located in the second color emission area RLA, and the third auxiliary wiring layer ML3 located in the third color emission area BLA may be spaced apart from each other. The third auxiliary wiring layer ML3 located in the first color emission area GLA, the third auxiliary wiring layer ML3 located in the second color emission area RLA, and the third auxiliary wiring layer ML3 located in the third color emission area BLA may be arranged independently of each other. The third auxiliary wiring layer ML3 located in the first color emission area GLA, the third auxiliary wiring layer ML3 located in the second color emission area RLA, and the third auxiliary wiring layer ML3 located in the third color emission area BLA may be separated from each other.

The second auxiliary wiring layer ML2 and the third auxiliary wiring layer ML3 may be positioned in a portion overlapping with the light emitting layers EL1, EL2, and EL3 to be described later. The second auxiliary wiring layer ML2 and the third auxiliary wiring layer ML3 may overlap with the first electrode E1 to be described later along the thickness direction (i.e., third direction DR3). The second auxiliary wiring layer ML2 and the third auxiliary wiring layer ML3 may not overlap with adjacent different emission areas and may be spaced apart from them.

The width of the third auxiliary wiring layer ML3 in cross-section may be greater than the width of the second auxiliary wiring layer ML2 in cross-section. The third auxiliary wiring layer ML3 may protrude more than the second auxiliary wiring layer ML2 in cross-section. The end of the third auxiliary wiring layer ML3 may form an undercut structure. The end of the second auxiliary wiring layer ML2 may be located inward from the end of the third auxiliary wiring layer ML3.

A first insulation layer ILa and a second insulation layer ILb may be sequentially positioned on the third auxiliary wiring layer ML3. The first insulation layer ILa may include inorganic insulating material, for example, silicon nitride, silicon oxide, or silicon oxynitride. The second insulation layer ILb may include organic insulating materials such as polyacrylic resin, polyimide resin, and/or inorganic insulating material.

The second insulation layer ILb may overlap with at least a portion of the first electrode E1 corresponding to each. The second insulation layer ILb may cover the edge of the first electrode E1. The second insulation layer ILb may define therein an opening that exposes the center portion of the first electrode E1.

The first electrode E1 may be positioned on the first insulation layer ILa. The first electrode E1 may be electrically connected to a transistor located in the pixel circuit portion PC through a contact hole to receive data voltage or current. FIGS. 6-7 do not show the structure in which the first electrode E1 is electrically connected to the pixel circuit portion PC, but the structure in which the first electrode E1 and the pixel circuit portion PC are connected can be explained through FIG. 9 to be described later.

The first electrode E1 located in the first to third color emission areas RLA, GLA, and BLA may be in an island shape, and the first electrode E1 of adjacent emission areas RLA, GLA, and BLA may be spaced apart from each other. The first electrode E1 located in the first color emission area GLA, the first electrode E1 located in the second color emission area RLA, and the first electrode E1 located in the third color emission area BLA may be arranged independently of each other. The first electrode E1 located in the first color emission area GLA, the first electrode E1 located in the second color emission area RLA, and the first electrode E1 located in the third color emission area BLA may be separated from each other.

The first electrode E1 may include semi-transparent conductive material, reflective conductive material, or transparent conductive material. The first electrode E1 may be formed as a single layer or multiple layers.

Light emitting layers EL1, EL2, and EL3 may be positioned on the first electrode E1 and the second insulation layer ILb. The light emitting layers EL1, EL2, and EL3 may be organic light emitting layers or inorganic light emitting layers and may include a host and a dopant. At least one of a hole injection layer and a hole transport layer may be positioned below the light emitting layers EL1, EL2, and EL3, or at least one of an electron transport layer and an electron injection layer may be positioned above the light emitting layers EL1, EL2, and EL3.

A first light emitting layer EL1 may be positioned in the first color emission area GLA. A second light emitting layer EL2 may be positioned in the second color emission area RLA. A third light emitting layer EL3 may be positioned in the third color emission area BLA. The first light emitting layer EL1, the second light emitting layer EL2, and the third light emitting layer EL3 may be spaced apart from each other.

A second electrode E2 may be positioned above the light emitting layers EL1, EL2, and EL3. The second electrode E2 may include transparent conductive material or reflective conductive material. The thickness of the second electrode E2 may be about 500 angstroms (Å) to about 1500 angstroms (Å).

The second electrode E2 may include at least one metal such as lithium (Li), copper (Cu), aluminum (Al), magnesium (Mg), silver (Ag), gold (Au), platinum (Pt), palladium (Pd), nickel (Ni), neodymium (Nd), iridium (Ir), molybdenum (Mo), tungsten (W), titanium (Ti), chromium (Cr), tantalum (Ta), or alloys thereof.

Also, the second electrode E2 may include TCO (Transparent Conductive Oxides), which is a transparent conductive material, for example, ITO (Indium Tin Oxide), ZnO (Zinc Oxide), AZO (Aluminum-doped Zinc Oxide), FTO (Fluorine-doped Tin Oxide), SnO₂ (Tin Oxide), or the like.

The second electrode E2 may be provided as a single layer or in multiple layers. For example, the second electrode E2 may include a first sublayer containing a metal material and a second sublayer containing a transparent conductive material. For example, the second electrode E2 may be provided in a multi-layer form comprising a first sublayer containing Ag-Mg and a second sublayer containing ITO.

The thickness of the second electrode E2 may be about 50 angstroms to about 2000 angstroms. For example, the thickness of the first sublayer may be smaller than the thickness of the second sublayer. The first sublayer may have a thickness of about 50 to 150 angstroms (Å), and the second sublayer may have a thickness of about 500 to 1500 angstroms (Å). However, it is not limited thereto, and the second electrode E2 may be provided as a single layer including a metal material.

The second electrode E2 may be spaced apart from each other for each of the first to third color emission areas GLA, RLA, and BLA. The second electrode E2 located in each emission area GLA, RLA, and BLA may be in an island shape. The second electrode E2 located in the first color emission area GLA, the second electrode E2 located in the second color emission area RLA, and the second electrode E2 located in the third color emission area BLA may be arranged independently of each other. The second electrode E2 located in the first color emission area GLA, the second electrode E2 located in the second color emission area RLA, and the second electrode E2 located in the third color emission area BLA may be separated from each other.

Here, the first electrode E1 is an anode, which is a hole injection electrode, and the second electrode E2 may be a cathode, which is an electron injection electrode. However, the embodiment is not necessarily limited thereto, and according to the driving method of the organic light emitting display device, the first electrode E1 may be a cathode, and the second electrode E2 may be an anode.

Holes and electrons are injected into the light emitting layers EL1, EL2, and EL3 from the first electrode E1 and the second electrode E2, respectively, and light emission occurs when an exciton formed by the combination of the injected holes and electrons drops from an excited state to a ground state.

The first electrode E1, the first light emitting layer EL1, and the second electrode E2 may form a first light emitting element ED1. The first electrode E1, the second light emitting layer EL2, and the second electrode E2 may form a second light emitting element ED2. The first electrode E1, the third light emitting layer EL3, and the second electrode E2 may form a third light emitting element ED3. The first light emitting element ED1 may emit green light, the second light emitting element ED2 may emit red light, and the third light emitting element ED3 may emit blue light.

An encapsulation layer ENC may be positioned above the first light emitting element ED1, the second light emitting element ED2, and the third light emitting element ED3. The encapsulation layer ENC may include a first inorganic layer EIL1, an organic layer EOL, and a second inorganic layer EIL2.

A first inorganic layer EIL1 may be positioned above the second electrode E2. The first inorganic layer EIL1 may include inorganic material, and may include silicon nitride, silicon oxide, or silicon oxynitride.

The first inorganic layer EIL1 may be in an island shape. The first inorganic layer EIL1 located in the first color emission area GLA, the first inorganic layer EIL1 located in the second color emission area RLA, and the first inorganic layer EIL1 located in the third color emission area BLA may be spaced apart from each other. The first inorganic layer EIL1 located in the first color emission area GLA may encapsulate the first light emitting element ED1. The first inorganic layer EIL1 located in the second color emission area RLA may encapsulate the second light emitting element ED2. The first inorganic layer EIL1 located in the third color emission area BLA may encapsulate the third light emitting element ED3.

The first inorganic layer EIL1 may be separated from each other while encapsulating each emission area RLA, GLA, and BLA. According to embodiments, the first inorganic layer EIL1 may contact the upper surface of the second electrode E2, the side surface of the second electrode E2, a portion of the lower surface of the third auxiliary wiring layer ML3, and a portion of the auxiliary electrode E2a. The first inorganic layer EIL1 may seal each of the first light emitting element ED1, the second light emitting element ED2, and the third light emitting element ED3 without separate spaces.

According to embodiments, because each of the first to third color emission areas RLA, GLA, and BLA is sealed separately, even if one pixel becomes defective due to defect factors such as moisture permeation, it can prevent the defect factors from spreading to neighboring pixels, thus reducing the defect rate of all pixels of the display device and preventing leakage current between pixels. However, not limited to this, in a display device according to another embodiment, the first inorganic layer EIL1 may be continuously (monolithically) positioned over the entire front surface of the substrate SUB. The first inorganic layer EIL1 located in the first color emission area GLA, the first inorganic layer EIL1 located in the second color emission area RLA, and the first inorganic layer EIL1 located in the third color emission area BLA may be connected to each other.

An organic layer EOL may be positioned on the first inorganic layer EIL1. The organic layer EOL may include organic materials such as acrylic resin layer, methacrylic resin layer, polyisoprene, vinyl resin layer, epoxy resin layer, urethane resin layer, cellulose resin layer, and perylene resin layer.

The organic layer EOL may be positioned across the first to third color emission areas GLA, RLA, and BLA. The organic layer EOL located in the first color emission area GLA, the organic layer EOL located in the second color emission area RLA, and the organic layer EOL located in the third color emission area BLA are connected to each other. The organic layer EOL may be continuously (monolithically) arranged across the first to third color emission areas GLA, RLA, and BLA.

The organic layer EOL may be positioned between the spaced apart first inorganic layers EIL1. The organic layer EOL may contact the upper surface of the first inorganic layer EIL1, the side surface of the first inorganic layer EIL1, and a portion of the upper surface of the auxiliary electrode E2a. Because adjacent first inorganic layers EIL1 are spaced apart from each other, a portion of the auxiliary electrode E2a may be exposed. The exposed auxiliary electrode E2a may be located between the first light emitting element ED1 and the second light emitting element ED2, between the second light emitting element ED2 and the third light emitting element ED3, and between the third light emitting element ED3 and the first light emitting element ED1. The exposed auxiliary electrode E2a may be covered by the organic layer EOL.

A second inorganic layer EIL2 may be positioned on the organic layer EOL. The second inorganic layer EIL2 may include inorganic material, and may include silicon nitride, silicon oxide, or silicon oxynitride. The second inorganic layer EIL2 may be continuously (monolithically) positioned across the first to third color emission areas GLA, RLA, and BLA.

According to embodiments, a plurality of color conversion layers and transmission layers may be positioned on the encapsulation layer. The color conversion layer may include semiconductor nanocrystals containing at least one of a phosphor and a quantum dot material that converts light of an incident color into light of another color. According to embodiments, a plurality of color filters and light blocking members may be further positioned on the plurality of color conversion layers and transmission layers.

Hereinafter, a more specific structure will be examined based on the first light emitting element located in the first color emission area with reference to FIGS. 7-8. The description of the first color emission area in FIGS. 7 and 8 may also be applied to the second and third color emission areas in FIGS. 5 and 6.

According to FIG. 7, the ends of the first light emitting layer EL1, the second insulation layer ILb, the first insulation layer ILa, and the third auxiliary wiring layer ML3 may be aligned. The edges of the first light emitting layer EL1, the second insulation layer ILb, the first insulation layer ILa, and the third auxiliary wiring layer ML3 may overlap with each other. The first light emitting layer EL1, the second insulation layer ILb, the first insulation layer ILa, and the third auxiliary wiring layer ML3 may be manufactured in an etching process using the same photosensitive pattern. Therefore, the ends of the first light emitting layer EL1, the second insulation layer ILb, the first insulation layer ILa, and the third auxiliary wiring layer ML3 may form a flat side surface.

In cross-section, the ends of the first light emitting layer EL1, the second insulation layer ILb, the first insulation layer ILa, and the third auxiliary wiring layer ML3 may have a tapered shape while forming one side surface. Here, a tapered shape may refer to a shape in which the end gradually narrows and slopes. Also, because the first light emitting layer EL1, the second insulation layer ILb, and the first insulation layer ILa may be etched in the same process with the same photosensitive pattern, they may have substantially aligned side surfaces. The side surface of the first light emitting layer EL1, the side surface of the second insulation layer ILb, and the side surface of the first insulation layer ILa may form one side surface in cross-section. Forming one side surface may mean forming a smooth single surface without protrusions. The side surface of the first light emitting layer EL1, the side surface of the second insulation layer ILb, and the side surface of the first insulation layer ILa may have a shape that is inclined with respect to the third direction DR3.

In cross-section, the first light emitting layer EL1, the second insulation layer ILb, the first insulation layer ILa, and the third auxiliary wiring layer ML3 may form an aligned slope with each other. That is, the ends of the first light emitting layer EL1, the second insulation layer ILb, the first insulation layer ILa, and the third auxiliary wiring layer ML3 may be connected in a tapered shape along a single slope. In cross-section, the ends (e.g., side surfaces) of the first light emitting layer EL1, the second insulation layer ILb, the first insulation layer ILa, and the third auxiliary wiring layer ML3 may have a tapered shape inclined at the same angle. The ends of the first light emitting layer EL1, the second insulation layer ILb, the first insulation layer ILa, and the third auxiliary wiring layer ML3 may form the same inclined surface with respect to a lower surface of the third auxiliary wiring layer ML3.

The first light emitting layer EL1 may be positioned only on the upper surface of the first electrode E1 and the second insulation layer ILb. The first light emitting layer EL1 may be spaced apart from the side surfaces of the first electrode E1 and the second insulation layer ILb. The first light emitting layer EL1 may not contact the side surfaces of the first electrode E1 and the second insulation layer ILb. Also, the first light emitting layer EL1 may be spaced apart from the side surface of the third auxiliary wiring layer ML3. The first light emitting layer EL1 may not contact the side surface of the third auxiliary wiring layer ML3.

The ends of the first light emitting layer EL1, the second insulation layer ILb, the first insulation layer ILa, and the third auxiliary wiring layer ML3 may protrude more than the end of the second auxiliary wiring layer ML2. The end of the second auxiliary wiring layer ML2 may be located inward from the ends of the first light emitting layer EL1, the second insulation layer ILb, the first insulation layer ILa, and the third auxiliary wiring layer ML3.

The second electrode E2 may contact the upper surface of the first light emitting layer EL1, the side surface of the first light emitting layer EL1, the side surface of the second insulation layer ILb, the side surface of the first insulation layer ILa, and the side surface of the third auxiliary wiring layer ML3. The second electrode E2 may cover the upper surface of the first light emitting layer EL1, the side surface of the first light emitting layer EL1, the side surface of the second insulation layer ILb, the side surface of the first insulation layer ILa, and the side surface of the third auxiliary wiring layer ML3. The end of the second electrode E2 may extend to the side surface of the third auxiliary wiring layer ML3, and according to embodiments, may cover a portion of the lower surface of the third auxiliary wiring layer ML3.

The second electrode E2 may have a shape that encapsulates the first light emitting layer EL1. The second electrode E2 may have a shape that surrounds all surfaces of the first light emitting layer EL1 except for the lower surface. Also, the second electrode E2 may extend further downward than the first electrode E1. The minimum distance between the second electrode E2 and the substrate SUB may be smaller than the minimum distance between the first electrode E1 and the substrate SUB. Because the second electrode E2 needs to be connected to the auxiliary wiring layer ML, it may extend closer to the substrate SUB.

The second electrode E2 may contact the third auxiliary wiring layer ML3. As shown in FIG. 8, the second electrode E2 and the third auxiliary wiring layer ML3 may have a contact surface CS. The second electrode E2 may receive a common voltage from the third auxiliary wiring layer ML3, specifically from the auxiliary wiring layer ML. The second electrode E2 may stably receive a common voltage through a surface-type contact. As the first light emitting layer EL1 is positioned only on the upper surface of the first electrode E1 and the second insulation layer ILb, the second electrode E2 may directly contact the side surface of the third auxiliary wiring layer ML3 with the same slope as the side surface of the first light emitting layer EL1.

Alternatively, according to embodiments, the second electrode E2 may cover not only the side surface of the third auxiliary wiring layer ML3 but also at least a portion of the lower surface. The second electrode E2 may form a stable contact while wrapping around the end of the third auxiliary wiring layer ML3. The second electrode E2 can effectively receive the common voltage.

Referring back to FIG. 7, an auxiliary electrode E2a may be positioned on the first auxiliary wiring layer ML1. The auxiliary electrode E2a may be formed in the same process as the second electrode E2. The auxiliary electrode E2a and the second electrode E2 may be spaced apart from each other by the undercut of the auxiliary wiring layer ML. However, it is not limited thereto, and the auxiliary electrode E2a and the second electrode E2 may be connected with a very thin thickness. When the auxiliary electrode E2a and the second electrode E2 are connected with a thin thickness, they may be electrically separated due to relatively high resistance.

The auxiliary electrode E2a may cover the upper surface of the first auxiliary wiring layer ML1 and the side surface of the second auxiliary wiring layer ML2. The second electrode E2 and the auxiliary electrode E2a may have a separated form at the lower surface of the third auxiliary wiring layer ML3. The auxiliary electrode E2a may contact the first auxiliary wiring layer ML1 and reduce resistance.

Hereinafter, the laminated structure of the pixel circuit portion PC connected to the first electrode E1 will be specifically examined with reference to FIGS. 9 and 10. Description of the same components as previously described will be omitted. The laminated structures in FIGS. 6 and 8 are cross-sectional views of different parts in one emission area, so the specific laminated structures may be different.

Referring to FIGS. 9 and 10, a buffer layer BF may be positioned on the substrate SUB. According to embodiments, the buffer layer BF may be omitted. The buffer layer BF may include silicon nitride, silicon oxide, silicon oxynitride, or the like. The buffer layer BF can improve the characteristics of polycrystalline silicon by blocking impurities from the substrate SUB during the crystallization process for forming polycrystalline silicon. Also, the buffer layer BF can reduce the stress of the semiconductor layer ACT formed on the buffer layer BF by planarizing the substrate SUB.

A semiconductor layer ACT is positioned on the buffer layer BF. The semiconductor layer ACT may include polycrystalline silicon or oxide semiconductor. The semiconductor layer ACT includes a channel region C, a source region S, and a drain region D. The source region S and the drain region D are arranged on both sides of the channel region C. The channel region C includes an intrinsic semiconductor with no or minimal impurity doping, and the source region S and the drain region D include impurity semiconductors doped with conductive impurities. The semiconductor layer ACT may also be made of an oxide semiconductor, in which case a separate protection layer (not shown) may be added to protect the oxide semiconductor material, which is vulnerable to external environments such as high temperature.

A first gate insulation layer GI1 is positioned on the semiconductor layer ACT. The first gate insulation layer GI1 may be a single layer or a multi-layer including at least one of silicon nitride, silicon oxide, and silicon oxynitride.

A gate electrode GE1 may be positioned on the first gate insulation layer GI1. The gate electrode GE1 may overlap with the channel region C of the semiconductor layer ACT in a plan view. The gate electrode GE1 may be a multi-layer with a metal layer including one of copper (Cu), copper alloy, aluminum (Al), aluminum alloy, molybdenum (Mo), and molybdenum alloy.

A second gate insulation layer GI2 may be positioned on the gate electrode GE1. The second gate insulation layer GI2 may be a single layer or a multi-layer including at least one of silicon nitride, silicon oxide, and silicon oxynitride.

A storage electrode GE2 may be positioned on the second gate insulation layer GI2. The storage electrode GE2 may overlap with the gate electrode GE1 in a plan view to form a capacitor. A first interlayer insulation layer IL1 may be positioned on the storage electrode GE2.

A source electrode SE and a drain electrode DE are positioned on the first interlayer insulation layer IL1. The source electrode SE and the drain electrode DE are electrically connected to the source region S and the drain region D of the semiconductor layer ACT, respectively, through openings defined in a plurality of insulation layers.

A second interlayer insulation layer IL2 may be positioned on the source electrode SE and the drain electrode DE. The second interlayer insulation layer IL2 may include inorganic insulating material or organic insulating material.

A connection electrode CE may be positioned on the second interlayer insulation layer IL2. The connection electrode CE may electrically connect the first electrode E1 and the drain electrode DE. The connection electrode CE may include a metal single layer or multiple layers containing materials such as copper (Cu), molybdenum (Mo), titanium (Ti), aluminum (Al), or the like. This specification illustrates an embodiment in which the first electrode E1 and the drain electrode DE are electrically connected through the connection electrode CE, but it is not limited thereto, and an embodiment in which the first electrode E1 and the drain electrode DE are connected without the connection electrode CE is also possible.

A third interlayer insulation layer IL3 may be positioned on the connection electrode CE. The third interlayer insulation layer IL3 may be made of organic materials such as polyacrylates resin, polyimides resin, or a laminated layer of organic and inorganic materials.

An auxiliary wiring layer ML may be positioned on the third interlayer insulation layer IL3. The auxiliary wiring layer ML may be removed in an area where the first electrode E1 contacts the transistor, as shown in FIG. 10.

A first insulation layer ILa may be positioned on the auxiliary wiring layer ML. A first electrode E1 may be positioned on the first insulation layer ILa. The first electrode E1 may be connected to the connection electrode CE through an opening defined in the first insulation layer ILa and the third interlayer insulation layer IL3.

The transistor consisting of the gate electrode GE1, the semiconductor layer ACT, the source electrode SE, and the drain electrode DE may be electrically connected to the first electrode E1 to supply driving current to the light emitting element. The display device according to this embodiment may further include, in addition to the driving transistor shown in FIG. 9, a switching transistor (not shown) connected to a data line and transferring a data voltage in response to a scan signal, and a compensation transistor (not shown) connected to the driving transistor and compensating for the threshold voltage of the driving transistor in response to a scan signal.

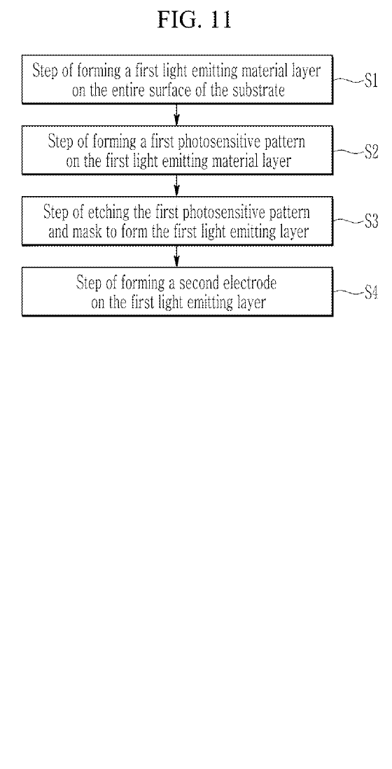

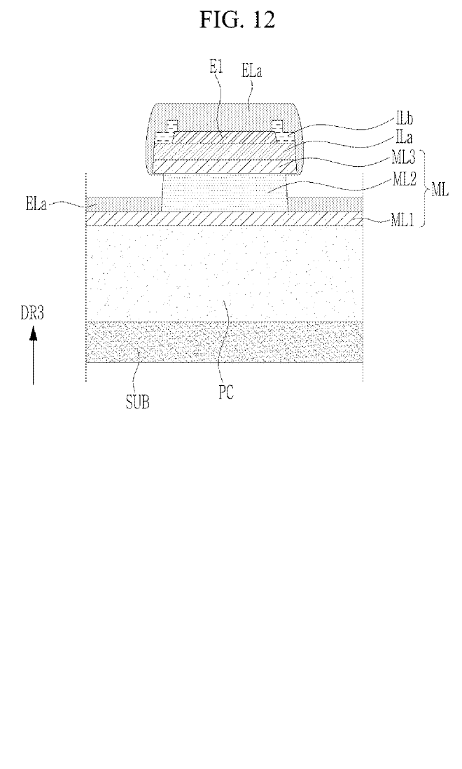

Hereinafter, a manufacturing method of a display device according to an embodiment will be examined with reference to FIGS. 11 to 14. FIG. 11 is a flowchart of a manufacturing process of a display device according to an embodiment, and FIGS. 12, 13, and 14 are cross-sectional views of the manufacturing process of a display device according to an embodiment. Description of the same components as previously described may be omitted.

Referring first to FIGS. 11 and 12, an auxiliary wiring layer ML is formed on a pixel circuit portion PC. The auxiliary wiring layer ML may include a first auxiliary wiring layer ML1, a second auxiliary wiring layer ML2, and a third auxiliary wiring layer ML3. A first insulation layer ILa and a second insulation layer ILb may be positioned on the third auxiliary wiring layer ML3. A first electrode E1 may be positioned between the first insulation layer ILa and the second insulation layer ILb.

Then, a first light emitting material layer ELa is formed on the entire surface of the substrate SUB (S1 in FIG. 11). The first light emitting material layer ELa may be positioned on the first electrode E1. Also, the first light emitting material layer ELa may cover the upper surface and side surface of the second insulation layer ILb, the side surface of the first insulation layer ILa, and the third auxiliary wiring layer ML3. Also, the first light emitting material layer ELa may be positioned on the first auxiliary wiring layer ML1.

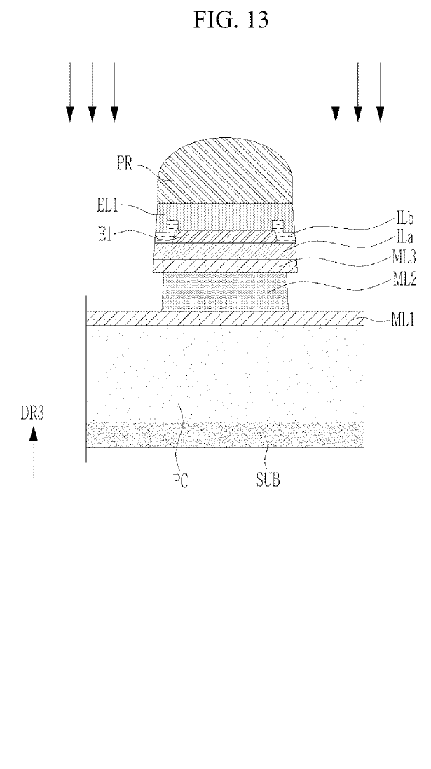

Next, a first photosensitive pattern PR is formed on the first light emitting material layer ELa as shown in FIG. 13 (S2 in FIG. 11). An etching process is performed using the first photosensitive pattern PR as a mask. According to embodiments, a dry etching process or a wet etching process may be performed. Through the etching process, a first light emitting layer EL1 may be formed as shown in FIG. 13 (S3 in FIG. 11). Also, a second insulation layer ILb, a first insulation layer ILa, and a third auxiliary wiring layer ML3 with ends aligned with the first light emitting layer EL1 may be formed. Through the etching process, the first light emitting material layer ELa positioned on the first auxiliary wiring layer ML1 may be removed.

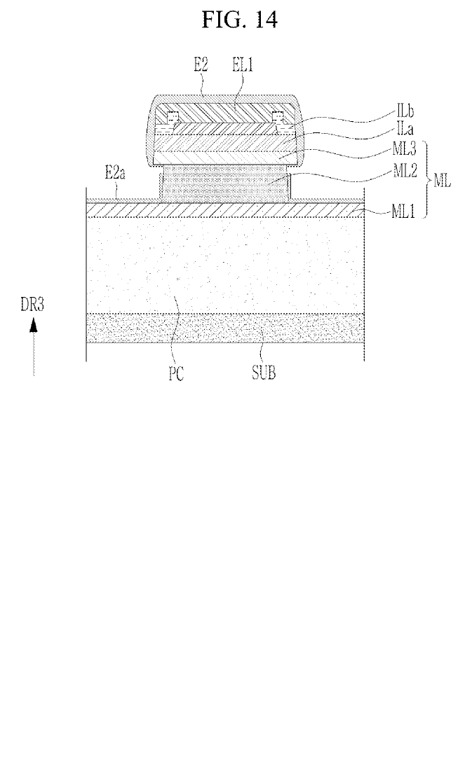

Then, as shown in FIG. 14, a second electrode E2 may be formed by depositing an electrode material on the first light emitting layer EL1 (S4 in FIG. 11). The second electrode E2 may be deposited on the entire surface of the substrate SUB. Due to the undercut shape between the third auxiliary wiring layer ML3 and the second auxiliary wiring layer ML2, the electrode material may be formed into a spaced apart second electrode E2 and auxiliary electrode E2a. The second electrode E2 and the auxiliary electrode E2a may be spaced apart from each other. However, it is not limited thereto, and the auxiliary electrode E2a and the second electrode E2 may be connected with a very thin thickness. When the auxiliary electrode E2a and the second electrode E2 are connected with a thin thickness, they may be electrically separated due to relatively high resistance.

The second electrode E2 may stably contact the third auxiliary wiring layer ML3. FIG. 14 shows an embodiment in which the second electrode E2 wraps around at least a portion of the lower surface of the third auxiliary wiring layer ML3, but is not limited thereto, and as explained earlier, an embodiment in which the second electrode E2 covers up to the side surface of the third auxiliary wiring layer ML3 is also possible. The second electrode E2 can receive a common voltage through stable contact with the third auxiliary wiring layer ML3.

According to the embodiment described above, the second electrode of the light emitting element can stably receive a common voltage by contacting the auxiliary wiring layer in a surface form. Therefore, the reliability of the light emitting element can be effectively improved.

While the embodiments of the present disclosure have been described in detail above, the scope of rights of the present disclosure is not limited thereto, and various modifications and improvements by those skilled in the art using the basic concept of the present disclosure defined in the following claims also belong to the scope of rights of the present disclosure.

What is claimed is:

1. A display device comprising:
a substrate;
a pixel circuit portion positioned on the substrate;
an auxiliary wiring layer positioned on the pixel circuit portion;
a first electrode positioned on the auxiliary wiring layer;
a light emitting layer positioned on the first electrode; and
a second electrode positioned on the light emitting layer and electrically connected to the auxiliary wiring layer,
wherein the auxiliary wiring layer includes:
a first auxiliary wiring layer positioned on the pixel circuit portion;
a second auxiliary wiring layer positioned on the first auxiliary wiring layer; and
a third auxiliary wiring layer positioned on the second auxiliary wiring layer,
wherein a side surface of the third auxiliary wiring layer and an outer side surface of the light emitting layer are coplanar to form a same inclined surface with respect to a lower surface of the third auxiliary wiring layer.

2. The display device of claim 1, further comprising:
a first insulation layer positioned between the third auxiliary wiring layer and the first electrode,
wherein an edge of the first insulation layer overlaps with an edge of the third auxiliary wiring layer.

3. The display device of claim 2, further comprising:
a second insulation layer positioned on the first insulation layer and the first electrode,
wherein another edge of the first insulation layer and an edge of the second insulation layer overlap with each other.

4. The display device of claim 3,
wherein the light emitting layer covers an upper surface of the second insulation layer and an upper surface of the first electrode.

5. The display device of claim 3,
wherein the light emitting layer is spaced apart from a side surface of the first insulation layer and a side surface of the second insulation layer.

6. The display device of claim 1,
wherein the second electrode contacts the side surface of the third auxiliary wiring layer.

7. The display device of claim 1,
wherein the third auxiliary wiring layer and the second auxiliary wiring layer form an undercut structure between the third auxiliary wiring layer and the second auxiliary wiring layer.

8. The display device of claim 1,
wherein the second auxiliary wiring layer and the third auxiliary wiring layer have an island shape.

9. The display device of claim 8,
wherein a width of the third auxiliary wiring layer is greater than a width of the second auxiliary wiring layer.

10. The display device of claim 1,
wherein the second electrode surrounds the light emitting layer and the first electrode.

11. The display device of claim 1, further comprising:
an auxiliary electrode positioned on the first auxiliary wiring layer.

12. The display device of claim 11,
wherein the auxiliary electrode includes a same material as the second electrode.

13. The display device of claim 12, further comprising:
a first inorganic layer positioned on the second electrode and the auxiliary electrode.

14. The display device of claim 13,
wherein the substrate includes a first color emission area, a second color emission area, and a third color emission area, and
wherein the second electrode is provided in plurality, the second electrodes are provided in the first color emission area, the second color emission area, and the third color emission area, respectively, and the second electrodes are spaced apart from each other.

15. The display device of claim 14,
wherein the first auxiliary wiring layer is monolithically arranged across the first color emission area, the second color emission area, and the third color emission area.

16. The display device of claim 14,
wherein the first inorganic layer is provided in plurality, the first inorganic layers are provided in the first color emission area, the second color emission area, and the third color emission area, respectively, and the first inorganic layers are spaced apart from each other.

17. An electronic device comprising a display device,
wherein the display device includes:
a substrate;
a pixel circuit portion positioned on the substrate;
an auxiliary wiring layer positioned on the pixel circuit portion;
a first electrode positioned on the auxiliary wiring layer;
a light emitting layer positioned on the first electrode; and
a second electrode positioned on the light emitting layer and electrically connected to the auxiliary wiring layer,
wherein the auxiliary wiring layer includes:
a first auxiliary wiring layer positioned on the pixel circuit portion;
a second auxiliary wiring layer positioned on the first auxiliary wiring layer; and
a third auxiliary wiring layer positioned on the second auxiliary wiring layer,
wherein a side surface of the third auxiliary wiring layer and an outer side surface of the light emitting layer are coplanar to form a same inclined surface with respect to a lower surface of the third auxiliary wiring layer.

18. The electronic device of claim 17,
wherein the electronic device is at least one of a smartphone, a tablet PC, a laptop, a TV, a desktop monitor, a wearable electronic device, and a vehicle electronic device.

19. An electronic device comprising a display device,
wherein the display device includes:
a substrate;
a pixel circuit portion positioned on the substrate;
an auxiliary wiring layer positioned on the pixel circuit portion;
a first electrode positioned on the auxiliary wiring layer;
a light emitting layer positioned on the first electrode; and
a second electrode positioned on the light emitting layer and connected to the auxiliary wiring layer,
wherein the auxiliary wiring layer includes:
a first auxiliary wiring layer positioned on the pixel circuit portion;
a second auxiliary wiring layer positioned on the first auxiliary wiring layer; and
a third auxiliary wiring layer positioned on the second auxiliary wiring layer,
wherein a width of the third auxiliary wiring layer is greater than a width of the second auxiliary wiring layer, and
wherein the light emitting layer is spaced apart from the auxiliary wiring layer.

20. The electronic device of claim 19, further comprising:
a first inorganic layer positioned on the second electrode,
wherein the first inorganic layer encapsulates the second electrode.
